(19) United States
(12) Patent Application Publication
(10) Pub. No.: US 2024/0128379 A1
(43) Pub. Date: Apr. 18, 2024

(54) ELECTRONIC DEVICE

(71) Applicant: InnoLux Corporation, Miao-Li County (TW)

(72) Inventor: Wang-Cheng CHUNG, Miao-Li County (TW)

(21) Appl. No.: 18/468,470

(22) Filed: Sep. 15, 2023

Related U.S. Application Data
(60) Provisional application No. 63/416,752, filed on Oct. 17, 2022.

(30) Foreign Application Priority Data
Jul. 7, 2023 (CN) 202310828367.1

(51) Int. Cl. H01L 29/786

(52) U.S. Cl. CPC H01L 29/78696; H01L 29/7869; H01L 29/41733

(57) ABSTRACT

An electronic device includes: a substrate; and a transistor disposed on the substrate, wherein the transistor includes: a gate electrode; a semiconductor layer at least partially overlapping the gate electrode, wherein the semiconductor layer includes a first sub-semiconductor layer and a second sub-semiconductor layer disposed on the first sub-semiconductor layer, and the second sub-semiconductor layer includes indium, gallium and zinc; a drain electrode electrically connected to the semiconductor layer; and a source electrode electrically connected to the semiconductor layer, wherein in the second sub-semiconductor layer, an atomic percentage of indium is less than an atomic percentage of gallium, and the atomic percentage of gallium is less than an atomic percentage of zinc.

### CROSS-REFERENCE TO RELATED APPLICATIONS

This application claims the benefits of the Chinese Patent Application Serial Number 202310828367.1, filed on Jul. 7, 2023, the subject matter of which is incorporated herein by reference.

This application claims the benefit of filing date of U.S. Provisional Application Ser. No. 63/416,752, filed Oct. 17, 2022 under 35 USC § 119(e)(1).

### BACKGROUND

### Field

The present disclosure relates to an electronic device. More specifically, the present disclosure relates to an electronic device for high voltage operation.

### Description of Related Art

Nowadays, thin-film transistors (TFTs) have been applied to various electronic devices, such as monitors, mobile phones, notebook computers, video cameras, cameras, music players, mobile navigation devices, TVs, tiled video wall or electronic paper, etc. However, TFTs in general electronic devices are mostly suitable for low-voltage operation and cannot withstand high voltage. When operating with high voltage, the TFT are easily burned out, causing the electronic device damaged.

Therefore, it is desirable to provide an electronic device applicable to high voltage operation.

### SUMMARY

The present disclosure provides an electronic device, which comprises: a substrate; and a transistor disposed on the substrate, wherein the transistor comprises: a gate electrode; a semiconductor layer at least partially overlapping the gate electrode, wherein the semiconductor layer comprises a first sub-semiconductor layer and a second sub-semiconductor layer disposed on the first sub-semiconductor layer, and the second sub-semiconductor layer comprises indium, gallium and zinc; a drain electrode electrically connected to the semiconductor layer; and a source electrode electrically connected to the semiconductor layer, wherein in the second sub-semiconductor layer, an atomic percentage of indium is less than an atomic percentage of gallium, and the atomic percentage of gallium is less than an atomic percentage of zinc.

The present disclosure also provides another electronic device, which comprises: a substrate; and a transistor disposed on the substrate, wherein the transistor comprises: a gate electrode; a semiconductor layer at least partially overlapping the gate electrode, wherein the semiconductor layer comprises a first sub-semiconductor layer and a second sub-semiconductor layer disposed on the first sub-semiconductor layer, and the second sub-semiconductor layer comprises indium, gallium and zinc; a drain electrode electrically connected to the semiconductor layer; and a source electrode electrically connected to the semiconductor layer, wherein a thickness of the drain electrode is less than a thickness of the semiconductor layer, and a thickness of the source electrode is less than the thickness of the semiconductor layer.

Other novel features of the disclosure will become more apparent from the following detailed description when taken in conjunction with the accompanying drawings.

### BRIEF DESCRIPTION OF DRAWINGS

FIG. 1 is a schematic cross-sectional view of an electronic device according to one embodiment of the present disclosure.

FIG. 2 is a graph showing the relationship between the voltage of the gate electrode and the current of the drain electrode of an electronic device according to one embodiment and a comparative embodiment of the present disclosure.

FIG. 3 is a graph showing the relationship between the voltage of the gate electrode and the current of the drain electrode of the electronic device under different voltages according to one embodiment of the present disclosure.

FIG. 4 is an equivalent circuit diagram of a pixel of an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names.

In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “equal to”, “equal” or “same”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the measurement of width, thickness and distance may be achieved by using an optical microscope or from a cross-sectional image of an electron microscope; but the present disclosure is not limited thereto. Furthermore, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

The electronic device of the present disclosure may include a display device, a backlight device, an antenna device, a sensing device or a tiled device, but the present disclosure is not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device for sensing capacitance, light, thermal energy or ultrasonic waves, but is not limited thereto. The tiled device may be, for example, a tiled display device or a tiled antenna device, but is not limited thereto. It should be noted that the electronic device may be any combination of the aforementioned device, but not limited thereto.

It should be noted that the technical solutions provided by different embodiments hereinafter may be replaced, combined or used in combination, so as to constitute another embodiment without violating the spirit of the present disclosure.

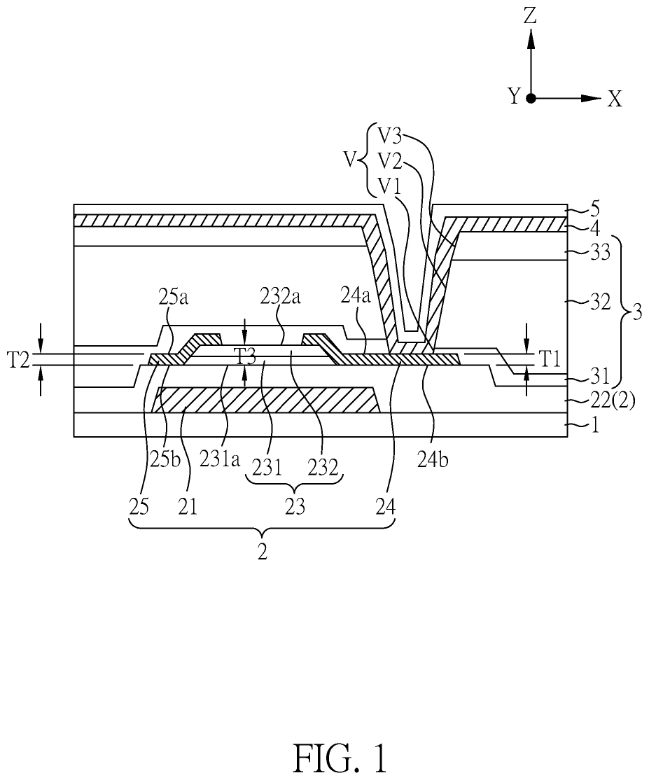

FIG. 1 is a schematic cross-sectional view of an electronic device according to one embodiment of the present disclosure.

In one embodiment of the present disclosure, as shown in FIG. 1, the electronic device may comprise: a substrate 1; and a transistor 2 disposed on the substrate 1. The transistor 2 may comprise: a gate electrode 21; a semiconductor layer 23 at least partially overlapping the gate electrode 21, wherein the semiconductor layer 23 comprises a first sub-semiconductor layer 231 and a second sub-semiconductor layer 232 disposed on the first sub-semiconductor layer 231, and the second sub-semiconductor layer 232 comprises indium, gallium and zinc; a drain electrode 24 electrically connected to the semiconductor layer 23; and a source electrode 25 electrically connected to the semiconductor layer 23. In the electronic device of the present disclosure, the high voltage resistance of the transistor 2 can be improved by designing the semiconductor layer 23 with multiple layers, so the electronic device can be applied to high voltage operation and the risk of the electronic device being burned out can be reduced.

In the present disclosure, the substrate 1 may be a rigid substrate or a flexible substrate. The material of substrate 1 may include quartz, glass, wafer, sapphire, resin, epoxy resin, polycarbonate (PC), polyimide (PI), polypropylene (PP), polyethylene terephthalate (PET), polymethylmethacrylate (PMMA), other plastic materials or a combination thereof, but the present disclosure is not limited thereto. In the present disclosure, the materials of the gate electrode 21, the drain electrode 24 and the source electrode 25 may be the same or different, wherein the materials of the gate electrode 21, the drain electrode 24 and the source electrode 25 may respectively comprise gold, silver, copper, palladium, platinum (Pt), ruthenium (Ru), aluminum, cobalt, nickel, titanium, molybdenum (Mo), manganese, zinc, an alloy thereof, or a combination thereof, but the present disclosure is not limited thereto

In one embodiment of the present disclosure, the first sub-semiconductor layer 231 may comprise indium, gallium, zinc and oxygen, wherein an atomic ratio of indium, gallium, zinc and oxygen in the first sub-semiconductor layer 231 is 1:1:1:4. Thus, the atomic percentage of indium is 14%, the atomic percentage of gallium is 14%, the atomic percentage of zinc is 14%, and the atomic percentage of oxygen is 58%. If oxygen is neglected, the atomic percentage of indium is 33%, the atomic percentage of gallium is 33%, and the atomic percentage of zinc is 33%. In one embodiment of the present disclosure, the material of the first sub-semiconductor layer 231 is indium gallium zinc oxide (IGZO). In the present disclosure, a thickness of the first sub-semiconductor layer 231 may range from 800 Å to 2000 Å, for example, 800 Å to 1800 Å, 800 Å to 1500 Å, 800 Å to 1200 Å, 1000 Å to 2000 Å, 1000 Å to 1500 Å or 1000 Å to 1200 Å, but the present disclosure is not limited thereto. By designing the thickness of the first sub-semiconductor layer 231 within a specific range, the high voltage resistance of the transistor 2 can be improved and the risk of electronic components being burned out can be reduced.

In the present disclosure, the atomic ratio of indium, gallium and zinc may be 1:3:2-8, for example, may be 1:3:6-8, in the second sub-semiconductor layer 232, but the present disclosure is not limited thereto. In one embodiment of the present disclosure, the atomic ratio of indium, gallium and zinc may be 1:3:2 in the second sub-semiconductor layer 232. In one embodiment of the present disclosure, if oxygen is neglected, the atomic ratio of indium, gallium and zinc may be 1:3:6 in the second sub-semiconductor layer 232. Thus, the atomic percentage of indium may be less than the atomic percentage of gallium, and the atomic percentage of gallium may be less than the atomic percentage of zinc. For example, the atomic percentage of indium is 10%, the atomic percentage of gallium is 30%, and the atomic percentage of zinc is 60%, but the present disclosure is not limited thereto. By designing the atomic ratio of indium, gallium and zinc in the second sub-semiconductor layer 232, the high voltage resistance of the transistor 2 can be improved and the risk of electronic components being burned out can be reduced. In one embodiment of the present disclosure, the material of the second sub-semiconductor layer 232 is indium gallium zinc oxide (IGZO). In the present disclosure, a thickness of the second sub-semiconductor layer 232 may range from 800 Å to 2000 Å, for example, 800 Å to 1800 Å, 800 Å to 1500 Å, 800 Å to 1200 Å, 1000 Å to 2000 Å, 1000 Å to 1500 Å or 1000 Å to 1200 Å, but the present disclosure is not limited thereto. By designing the thickness of the second sub-semiconductor layer 232 within a specific range, the high voltage resistance of the transistor 2 can be improved and the risk of electronic components being burned out can be reduced. In the present disclosure, if oxygen is neglected, the atomic percentage of indium in the second sub-semiconductor layer 232 (10%) may be less than the atomic percentage of indium in the first sub-semiconductor layer 231 (33%).

In the present disclosure, the semiconductor layer 23 and the gate electrode 21 at least partially overlapped means that the projection of the semiconductor layer 23 on the substrate 1 and the projection of the gate electrode 21 on the substrate 1 are at least partially overlapped in the normal direction Z of the substrate 1. In one embodiment of the present disclosure, an area of the projection of the semiconductor layer 23 on the substrate 1 is less than an area of the projection of the gate electrode 21 on the substrate 1.

In the present disclosure, as shown in FIG. 1, the transistor 2 may further comprise: a gate insulating layer 22 disposed on the gate electrode 21. In the present disclosure, the material of the gate insulating layer 22 may include silicon nitride, silicon oxide, silicon oxynitride, silicon carbonitride or a combination thereof, but the present disclosure is not limited thereto.

In the present disclosure, as shown in FIG. 1, the electronic device may further comprise: an insulating layer 3 disposed on the transistor 2; and a metal layer 4 disposed on the insulating layer 3, wherein the metal layer 4 may penetrate the insulating layer 3 to electrically connect to the drain electrode 24. More specifically, the metal layer 4 may electrically connect to the drain electrode 24 through the via V of the insulating layer 3. In one embodiment of the present disclosure, the insulating layer 3 may be designed for multiple layers. For example, as shown in FIG. 1, the insulating layer 3 may further comprise: a first insulating layer 31; a second insulating layer 32 disposed on the first insulating layer 31; and a third insulating layer 33 disposed on the second insulating layer 32. The metal layer 4 may electrically connect to the drain electrode 24 through the first via V1 of the first insulating layer 31, the second via V2 of the second insulating layer 32 and the third via V3 of the third insulating layer 33. In the present disclosure, as shown in FIG. 1, the electronic device may further comprise a conductive layer 5 disposed on the metal layer 4, wherein the conductive layer 5 may electrically connect to the drain electrode 24 through the metal layer 4.

In the present disclosure, the material of the insulating layer 3 may be an organic material, an inorganic material or a combination thereof. Suitable inorganic materials may include, for example, silicon nitride, silicon oxide, silicon oxynitride, silicon carbonitride, or a combination thereof, but the disclosure is not limited thereto. Suitable organic materials may include, for example, polycarbonate (PC), polyimide (PI), polypropylene (PP), polyethylene terephthalate (PET), polybenzoxazole (PBO), benzocyclobutene (ECB), polyfluoroalkoxy (PFA), epoxy resin, photoresist, polymer, or a combination thereof, but the present disclosure does not limited thereto. In one embodiment of the present disclosure, the materials of the first insulating layer 31, the second insulating layer 32 and the third insulating layer 33 may be the same or different. For example, the materials of the first insulating layer 31 and the third insulating layer 33 may be inorganic materials, and the material of the second insulating layer 32 may be an organic material, but the present disclosure is not limited thereto.

In the present disclosure, the material of the metal layer 4 may include gold, silver, copper, palladium, platinum (Pt), ruthenium (Ru), aluminum, cobalt, nickel, titanium, molybdenum (Mo), manganese, zinc, an alloy thereof, or a combination thereof, but the present disclosure is not limited thereto. In the present disclosure, the material of the conductive layer 5 may be a transparent conductive material, for example, may include indium zinc oxide (IZO), indium tin oxide (ITO), indium tin zinc oxide (ITZO), indium gallium zinc oxide (IGZO), aluminum zinc oxide (AZO), or a combination thereof, but the present disclosure is not limited thereto.

In one embodiment of the present disclosure, the thickness T1 of the drain electrode 24 is less than the thickness T3 of the semiconductor layer 23, and the thickness T2 of the source electrode 25 is less than the thickness T3 of the semiconductor layer 23. More specifically, as shown in FIG. 1, in the normal direction Z of the substrate 1, the drain electrode 24 has a thickness T1, the source electrode 25 has a thickness T2, and the semiconductor layer 23 has a thickness T3, wherein the thickness T1 is less than the thickness T3 (T1<T3), and the thickness T2 is less than the thickness T3 (T2<T3). In one embodiment of the present disclosure, the thickness T1 of the drain electrode 24 refers to the distance (for example, the maximum distance) between the upper surface 24a and the lower surface 24b of the drain electrode 24 in the normal direction Z of the substrate 1; the thickness T2 of the source electrode 25 refers to the distance (for example, the maximum distance) between the upper surface 25a and the lower surface 25b of the source electrode 25 in the normal direction Z of the substrate 1; and the thickness T3 of the semiconductor layer 23 refers to the total thickness of the first sub-semiconductor layer 231 and the second sub-semiconductor layer 232 in the normal direction Z of the substrate 1. More specifically, the thickness T3 of the semiconductor layer 23 is the distance (for example, the maximum distance) between the upper surface 232a of the second sub-semiconductor layer 232 and the lower surface 231a of the first sub-semiconductor layer 231. It should be noted that the thickness measurement position of any layer should try to avoid the end region of the layer or the region overlapped with other layers, because the thickness of these regions is usually non-uniform.

In the present disclosure, the gate electrode 21, the gate insulating layer 22, the semiconductor layer 23, the drain electrode 24, the source electrode 25, the insulating layer 3, the metal layer 4 and the conductive layer 5 may be respectively prepared by appropriate methods. The appropriate methods include electroplating, chemical plating, chemical vapor deposition, sputtering, coating, photolithography, or a combination thereof, but the present disclosure is not limited thereto. Herein, the coating method may be, for example, dip coating, spin coating, roller coating, blade coating, spray coating, or a combination thereof, but the present disclosure is not limited thereto.

In the present disclosure, even not shown in the figure, the electronic device may further comprise an opposite substrate, a color filter layer, a covering substrate, a touch layer, a display medium layer, a polarizer, a common electrode, other suitable electronic components, other suitable elements or a combination thereof. The electronic components may comprise passive components and active components, such as capacitors, resistors, inductors, diodes, transistors, and the like. The diodes may comprise light emitting diodes or photodiodes. The light emitting diodes may, for example, comprise organic light emitting diodes (OLEDs), mini light emitting diodes (mini LEDs), micro light emitting diodes (micro LEDs) or quantum dot light emitting diodes (quantum dot LEDs), but the present disclosure is not limited thereto. The electronic device of the present disclosure is an electronic device applicable to high voltage operation, such as a backlight device, a tiled device, an antenna device, a sensing device, a liquid crystal display, an OLED display, a mini LED display, a micro LED display, a cholesteric liquid crystal display, or an electrophoretic display, but the present disclosure is not limited thereto.

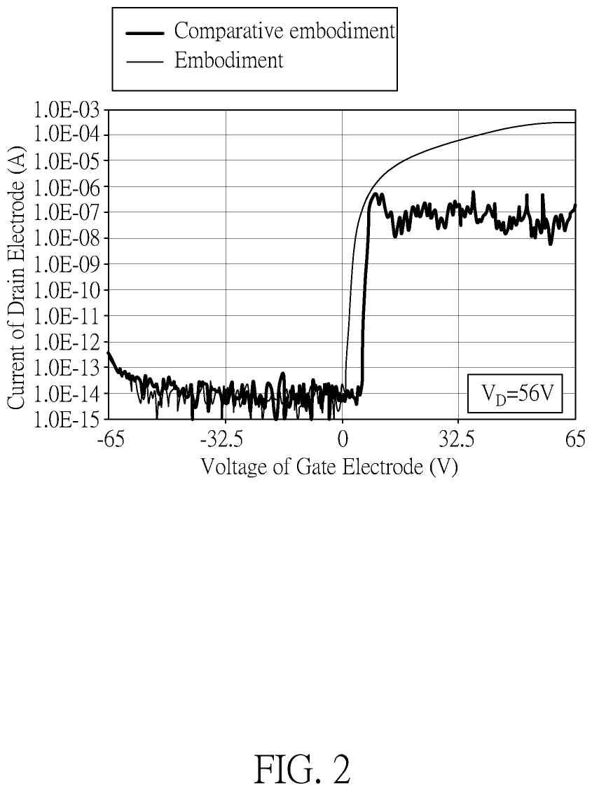

FIG. 2 is a graph showing the relationship between the voltage of the gate electrode and the current of the drain electrode of an electronic device according to one embodiment and a comparative embodiment of the present disclosure.

The electronic device shown in FIG. 1 was used as the embodiment of the present test, wherein the first sub-semiconductor layer 231 was an IGZO layer, and the atomic ratio of indium, gallium, and zinc was 1:1:1; and the second sub-semiconductor layer 232 was an IGZO layer, and the atomic ratio of indium, gallium, and zinc was 1:3:6. In addition, the thicknesses of the first sub-semiconductor layer 231 and the second sub-semiconductor layer 232 were respectively 1000 Å. The electronic device of the comparative embodiment used in the present test was prepared according to the design similar to the above, wherein the semiconductor layer 23 of the comparative embodiment had a single-layer design, and other components were the same as those of the embodiment. In other words, in the electronic device of the comparative embodiment, the semiconductor layer 23 comprised only the first sub-semiconductor layer 231 and did not comprise the second sub-semiconductor layer 232, wherein the first sub-semiconductor layer 231 was an IGZO layer, the atomic ratio of indium, gallium and zinc was 1:1:1, and the thickness of the first sub-semiconductor layer 231 was 1000 Å.

At an ambient temperature of 25° C., a voltage of 56 V was respectively applied to the electronic devices of the embodiment and the comparative embodiment to observe the relationship between the voltage of the gate electrode 21 and the current of the drain electrode 24 of each electronic device. The results are shown in FIG. 2. As shown in FIG. 2, when the semiconductor layer 23 of the electronic device had a single-layer design (i.e., the comparative embodiment), the transistor 2 was easily burned out due to high voltage, which affects the reliability of the electronic device. In contrast, when the semiconductor layer 23 of the electronic device had a double-layer design (i.e., the embodiment), the transistor 2 can withstand high voltage, thereby improving the reliability of the electronic device.

FIG. 3 is a graph showing the relationship between the voltage of the gate electrode and the current of the drain electrode of the electronic device under different voltages according to one embodiment of the present disclosure.

The electronic device shown in FIG. 1 was used as the embodiment of the present test, wherein the first sub-semiconductor layer 231 was an IGZO layer, and the atomic ratio of indium, gallium, and zinc was 1:1:1; and the second sub-semiconductor layer 232 was an IGZO layer, and the atomic ratio of indium, gallium, and zinc was 1:3:6. In addition, the thicknesses of the first sub-semiconductor layer 231 and the second sub-semiconductor layer 232 were respectively 1000 Å.

At an ambient temperature of 25° C., different voltages (such as 0.1 V, 28 V and 56 V) were respectively applied to the electronic device of the embodiment to observe the relationship between the voltage of the gate electrode 21 and the current of the drain electrode 24 of the electronic device under different voltages. The results are shown in FIG. 3. As shown in FIG. 3, when the semiconductor layer 23 of the electronic device had a double-layer design, the electronic device can be operated normally when voltages of 0.1 V to 56 V were applied to the transistor 2, and no degradation such as burning of the transistor 2 was observed.

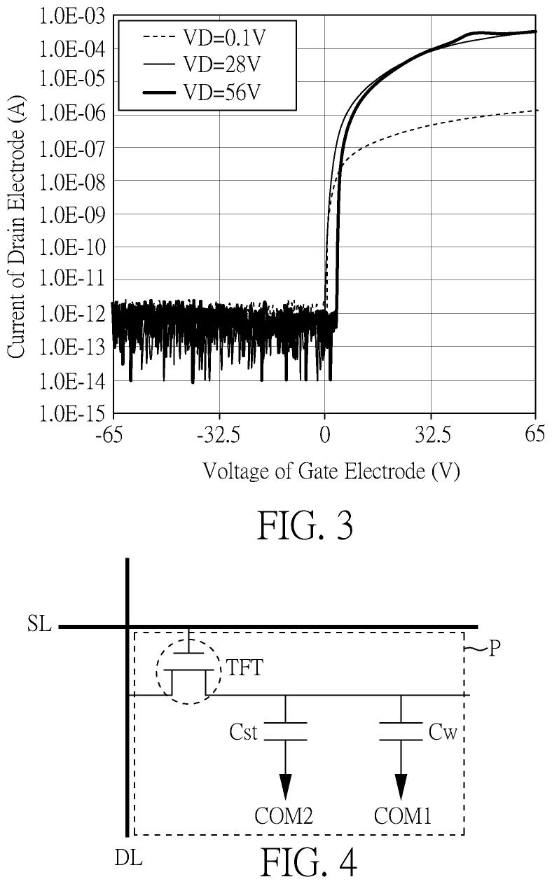

FIG. 4 is an equivalent circuit diagram of a pixel of an electronic device according to one embodiment of the present disclosure.

In one embodiment of the present disclosure, the electronic device may comprise a plurality of pixel units P disposed on substrate 1 (as shown in FIG. 1), and one of these pixel units P may be designed to have an equivalent circuit diagram as shown in FIG. 4. As shown in FIG. 4, the pixel unit P may include: a transistor TFT; a working capacitor Cw; and a storage capacitor Cst. The transistor TFT may have the structure shown as the transistor 2 in FIG. 1, and the transistor TFT is electrically connected to the working capacitor Cw and the storage capacitor Cst respectively. The first end of the working capacitor Cw is electrically connected to the first end of the storage capacitor Cst, the second end of the working capacitor Cw is electrically connected to an electrode COM1, and the second end of the storage capacitor Cst is electrically connected to another electrode COM2. In one embodiment of the present disclosure, the electrode COM1 and the electrode COM2 may receive the same common voltage or different voltages.

In one embodiment of the present disclosure, the electronic device may comprise a plurality of scan lines SL and a plurality of data lines DL disposed on a substrate (as shown in FIG. 1), wherein the plurality of scan lines SL and the plurality of data lines DL are arranged orthogonally to each other and form a pixel unit P. As shown in FIG. 4, the scan line signal and the data line signal may be respectively transmitted to the transistor TFT through the scan line SL and the data line DL, so as to drive the pixel unit P to display images. More specifically, the scan line SL is electrically connected to the gate electrode of the transistor TFT to transmit the scan line signal to the transistor TFT, and the data line DL is electrically connected to the source electrode of the transistor TFT to transmit the data line signal to the transistor TFT. Herein, in the present embodiment, a display device is used as an example of the electronic device, but the present disclosure is not limited thereto. The electronic device of the present disclosure, not limited to the display device, can withstand high voltage operation.

The specific embodiments above should be interpreted as illustrative only, not limiting the rest of the present disclosure in any way, and the features of different embodiments can be mixed and matched as long as they do not conflict with each other.

Although the present disclosure has been explained in relation to its embodiment, it is to be understood that many other possible modifications and variations can be made without departing from the spirit and scope of the disclosure as hereinafter claimed.

1. An electronic device, comprising:
a substrate; and
a transistor disposed on the substrate, wherein the transistor comprises:
a gate electrode;
a semiconductor layer at least partially overlapping the gate electrode, wherein the semiconductor layer comprises a first sub-semiconductor layer and a second sub-semiconductor layer disposed on the first sub-semiconductor layer, and the second sub-semiconductor layer comprises indium, gallium and zinc;
a drain electrode electrically connected to the semiconductor layer; and
a source electrode electrically connected to the semiconductor layer,
wherein in the second sub-semiconductor layer, an atomic percentage of indium is less than an atomic percentage of gallium, and the atomic percentage of gallium is less than an atomic percentage of zinc.

2. The electronic device of claim 1, wherein a thickness of the second sub-semiconductor layer ranges from 800 Å to 2000 Å.

3. The electronic device of claim 1, wherein an atomic ratio of indium, gallium and zinc is 1:3:6-8 in the second sub-semiconductor layer.

4. The electronic device of claim 1, wherein the first sub-semiconductor layer comprises indium, and the atomic percentage of indium in the second sub-semiconductor layer is less than an atomic percentage of indium in the first sub-semiconductor layer.

5. The electronic device of claim 1, wherein the first sub-semiconductor layer comprises indium, gallium and zinc, and an atomic ratio of indium, gallium and zinc is 1:1:1 in the first sub-semiconductor layer.

6. The electronic device of claim 1, wherein a thickness of the first sub-semiconductor layer ranges from 800 Å to 2000 Å.

7. The electronic device of claim 1, further comprising:
an insulating layer disposed on the transistor; and
a metal layer disposed on the insulating layer,
wherein the metal layer penetrates the insulating layer to electrically connect to the drain electrode.

8. The electronic device of claim 7, wherein the metal layer electrically connects to the drain electrode through a via of the insulating layer.

9. The electronic device of claim 7, further comprising: a conductive layer disposed on the metal layer and electrically connecting to the drain electrode through the metal layer.

10. An electronic device, comprising:
a substrate; and
a transistor disposed on the substrate, wherein the transistor comprises:
a gate electrode;
a semiconductor layer at least partially overlapping the gate electrode, wherein the semiconductor layer comprises a first sub-semiconductor layer and a second sub-semiconductor layer disposed on the first sub-semiconductor layer, and the second sub-semiconductor layer comprises indium, gallium and zinc;
a drain electrode electrically connected to the semiconductor layer; and
a source electrode electrically connected to the semiconductor layer,
wherein a thickness of the drain electrode is less than a thickness of the semiconductor layer, and a thickness of the source electrode is less than the thickness of the semiconductor layer.

11. The electronic device of claim 10, wherein a thickness of the second sub-semiconductor layer ranges from 800 Å to 2000 Å.

12. The electronic device of claim 10, wherein in the second sub-semiconductor layer, an atomic percentage of indium is less than an atomic percentage of gallium, and the atomic percentage of gallium is less than an atomic percentage of zinc.

13. The electronic device of claim 10, wherein an atomic ratio of indium, gallium and zinc is 1:3:6-8 in the second sub-semiconductor layer.

14. The electronic device of claim 10, wherein the first sub-semiconductor layer comprises indium, and an atomic percentage of indium in the second sub-semiconductor layer is less than an atomic percentage of indium in the first sub-semiconductor layer.

15. The electronic device of claim 10, wherein the first sub-semiconductor layer comprises indium, gallium and zinc, and an atomic ratio of indium, gallium and zinc is 1:1:1 in the first sub-semiconductor layer.

16. The electronic device of claim 10, wherein a thickness of the first sub-semiconductor layer ranges from 800 Å to 2000 Å.

17. The electronic device of claim 10, further comprising:
an insulating layer disposed on the transistor; and
a metal layer disposed on the insulating layer,
wherein the metal layer penetrates the insulating layer to electrically connect to the drain electrode.

18. The electronic device of claim 17, wherein the metal layer electrically connects to the drain electrode through a via of the insulating layer.

19. The electronic device of claim 17, further comprising: a conductive layer disposed on the metal layer and electrically connecting to the drain electrode through the metal layer.
